(19) United States
(12) Patent Application Publication
(10) Pub. No.: US 2014/0065743 A1
(43) Pub. Date: Mar. 6, 2014

(54) METHOD OF MANUFACTURING LIGHT EMITTING DIODE DIE

(71) Applicant: ADVANCED OPTOELECTRONIC TECHNOLOGY, INC., Hsinchu Hsien (TW)

(72) Inventors: YA-WEN LIN, Hsinchu (TW); SHIH-CHENG HUANG, Hsinchu (TW); PO-MIN TU, Hsinchu (TW)

(73) Assignee: ADVANCED OPTOELECTRONIC TECHNOLOGY, INC., Hsinchu Hsien (TW)

(21) Appl. No.: 13/966,652

(22) Filed: Aug. 14, 2013

(30) Foreign Application Priority Data
Aug. 31, 2012 (CN) 2012103176923

(51) Int. Cl. H01L 33/14

(52) U.S. Cl. CPC H01L 33/145
USPC 438/29

(57) ABSTRACT

An exemplary method of manufacturing a light emitting diode (LED) die includes steps: providing a preformed LED structure, the LED structure including a first substrate, and a nucleation layer, a buffer layer, an N-type layer, a muti-quantum well layer and an P-type layer formed successively on the first substrate; forming at least one insulation block on the P-type layer; forming a mirror layer on the on the P-type layer and covering the insulation block; forming a conductive second substrate on the mirror layer; removing the first substrate, the nucleation layer and the buffer layer and exposing a bottom surface of the N-type layer; and disposing one N-electrode on the exposed surface of the N-type layer. The N-electrode is located corresponding to the insulation block.

### BACKGROUND

1. Technical Field

The disclosure relates to a method for manufacturing a semiconductor structure, and more particularly to a method for manufacturing a light emitting diode (LED) die capable of to have current evenly flowing therein to improve the lighting efficiency of the LED die.

2. Description of the Related Art

LEDs have low power consumption, high efficiency, quick reaction time, long lifetime, and the absence of toxic elements such as mercury during manufacturing. Due to these advantages, traditional light sources are gradually replaced by LEDs.

When the LED works, current flowing from a P electrode to an N electrode is easily concentrated on the shortest path between the P electrode and the N electrode. The concentration of the current results in a brightness of an illumination area of the LED near the N electrode being greater than other illumination area away from the N electrode, and accordingly, the brightness of the LED is not uniform. In addition, a temperature of the illumination area of the LED near the electrodes is easily becoming higher and higher which leads to a life time of the LED be decreased.

Therefore, a manufacturing method of manufacturing the LED die that overcomes aforementioned deficiencies is required.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present method of manufacturing the LED die. Moreover, in the drawings, like reference numerals designate corresponding parts throughout the views.

FIGS. 1 to 6 are cross-sectional views showing steps of a method for manufacturing an LED die in accordance with a first embodiment of the disclosure.

FIGS. 7 to 13 are cross-sectional views showing steps of a method for manufacturing an LED die in accordance with a second embodiment of the disclosure.

### DETAILED DESCRIPTION

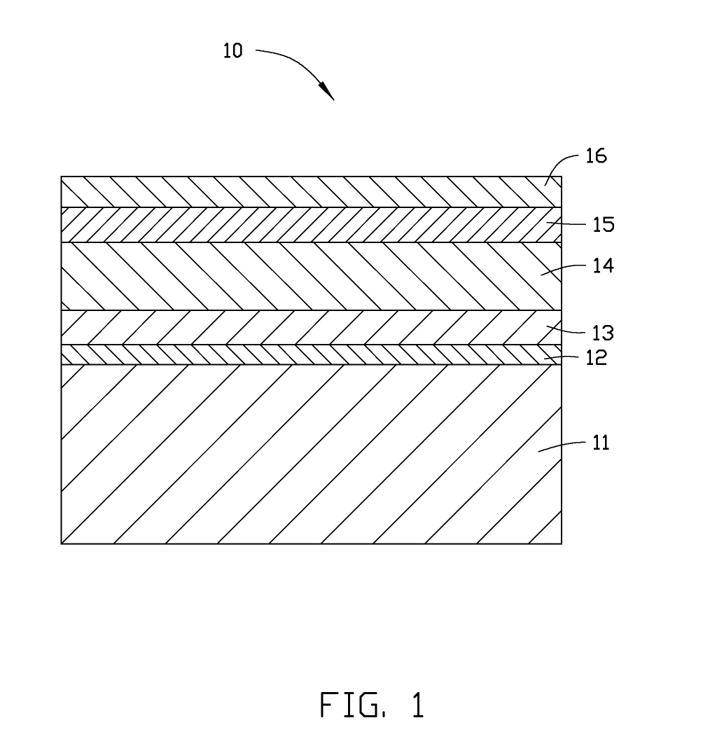

Referring to FIGS. 1 to 6, a method of manufacturing an LED die 100 in accordance with first embodiment of the disclosure is provided. The manufacturing method includes steps as following.

Referring FIG. 1, a preformed LED structure 10 is provided. The LED structure 10 includes a first substrate 11, a nucleation layer 12, a buffer layer 13, an N-type layer 14, a muti-quantum well layer 15 and a P-type layer 16 successively formed on the first substrate 11, along a height direction of the LED structure 10.

Specifically, the first substrate 11 is flat and can be made of materials such as sapphire, silicon carbide (SiC), silicon (Si) or gallium nitride (GaN) and so on. In this embodiment, the first substrate 11 is made of sapphire.

The nucleation layer 12, the buffer layer 13, the N-type layer 14, the muti-quantum well layer 15 and the P-type layer 16 are sequentially formed on the first substrate 11 by metal-organic chemical vapor deposition (MOCVD), molecular beam epitaxy (MBE) or hydride vapor phase epitaxy (HVPE). The nucleation layer 12 enhances a connection performance between the first substrate 11 and the buffer layer 13. The buffer layer 13 decreases crystal lattices dislocation between the nucleation layer 12 and the N-type layer 14. In this embodiment, the N-type layer 14 is N-type GaN, and the P-type layer 16 is P-type GaN.

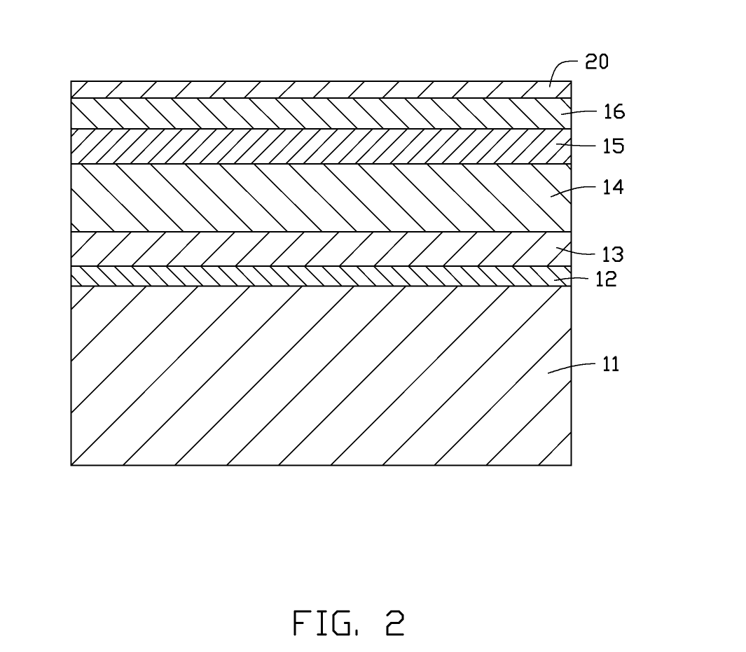

Referring to FIG. 2, an insulation layer 20 is formed on the P-type layer 16. The insulation layer 20 can be made of materials such as SiO₂, AlN, SiₓN_{y} and so on. In this embodiment, the insulation layer 20 is made of SiO₂.

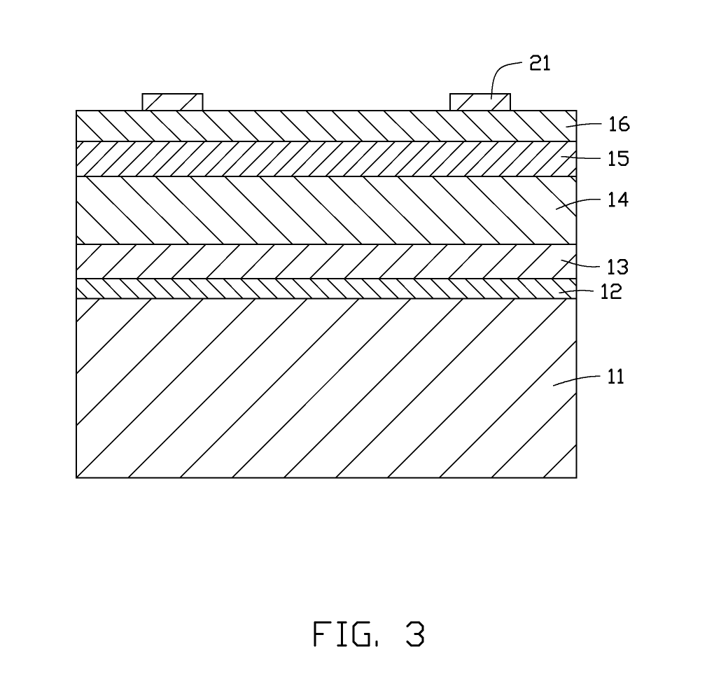

Referring to FIG. 3, the insulation layer 20 is etched to form a plurality of insulation blocks 21. The insulation blocks 21 are formed by photolithography etching the insulation layer 20. In this embodiment, the number of the insulation blocks 21 is two and the insulation blocks 21 are spaced from each other.

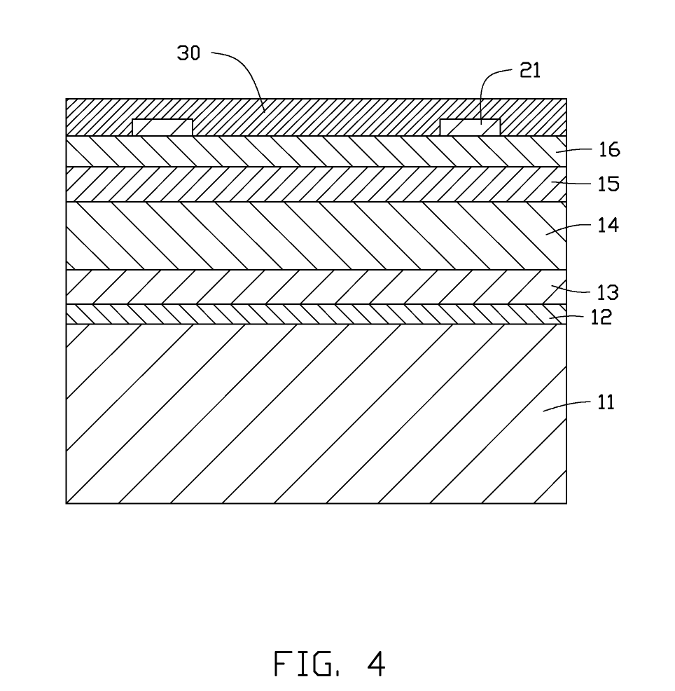

Referring to FIG. 4, a mirror layer 30 is formed on the P-type layer 16 to cover the insulation blocks 21. The mirror layer 30 is flat for improving light extracting efficiency of the LED die 100.

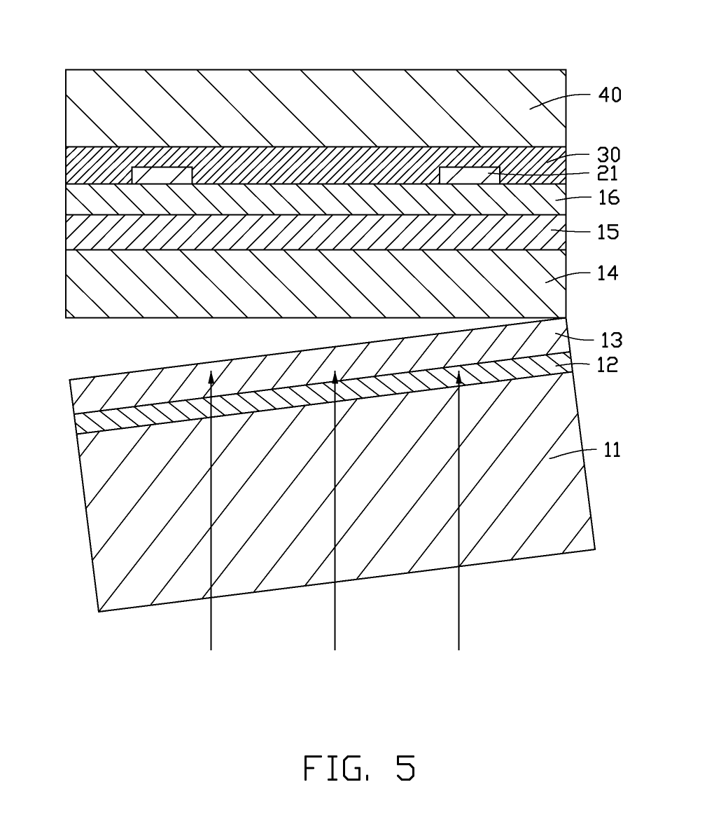

Referring to FIG. 5, a second substrate 40 is formed on the mirror layer 30 by electroplating or die bonding. The second substrate 40 is a metal substrate or a semiconductor substrate. The second substrate 40, when designed as a metal substrate, may be made of Ti, Al, Ag, Ni, W, Cu, Pd, Cr or Au. Then the first substrate 11, the nucleation layer 12 and the buffer layer 13 are removed from the LED structure 10 by laser separation method or chemical separation method, and a bottom surface of the N-type layer 14 originally adjacent to the buffer layer 13 is exposed.

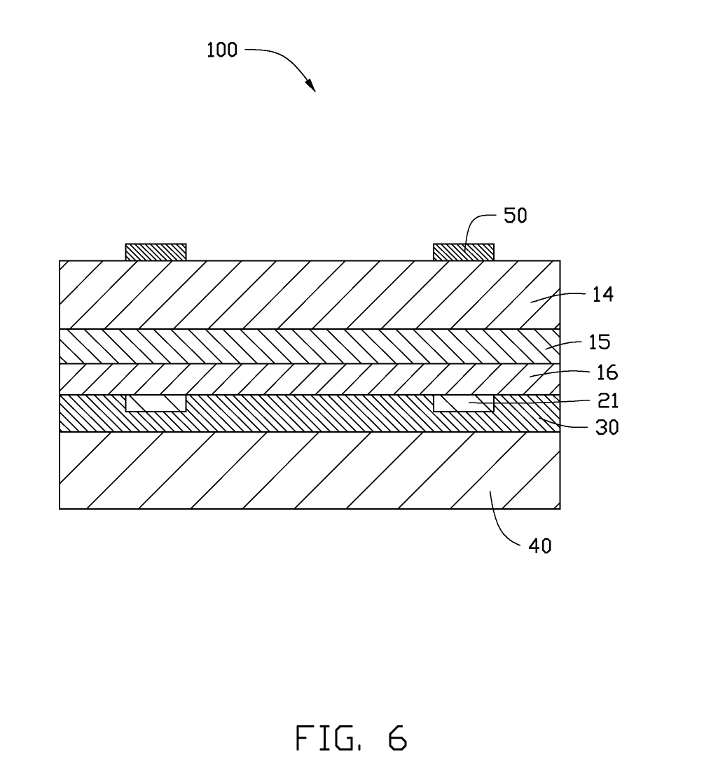

Referring to FIG. 6, the LED structure 10 is inverted, and two N-electrodes 50 are disposed on the exposed surface of the N-type layer 14 and located corresponding to the insulation blocks 21, respectively. The N-electrodes 50 may be made of materials such as Ti, Al, Ag, Ni, W, Cu, Pd, Cr or Au. Each N-electrode 50 has a size the same as that of each insulation block 21.

When the LED die 100 works, the second substrate 40 and the N-electrodes 50 are located at two opposite sides of the muti-quantum well layer 15 respectively. When a forward voltage is applied to the second substrate 40 and the N-electrodes 50, electrons inside the N-type layer 14 will be captured by electric holes inside the P-type layer 16 under excitation of an electric field, photons are emitted from the muti-quantum well layer 15 where the combinations of the electrons and the electric holes occur. Since the N-electrodes 50 are located corresponding to the insulation blocks 21, the shortest path for current between the second substrate 40 and the N-electrodes 50 are blocked by the insulation blocks 21, thereby making the current be dispersed in the LED die 100 more evenly. The current flowing from the second substrate 40 to the N-type electrodes 50, will go around two opposite sides of each of the insulation blocks 21 by dodging the insulation blocks 21. Accordingly, the current is more uniformly distributed in the LED die 100 to cause the LED die 100 to have a more uniform illumination and an enhanced lighting efficiency. Meanwhile, the life time of the LED die 100 is prolonged since heats generated by the LED die 100 are evenly distributed in the LED die 100.

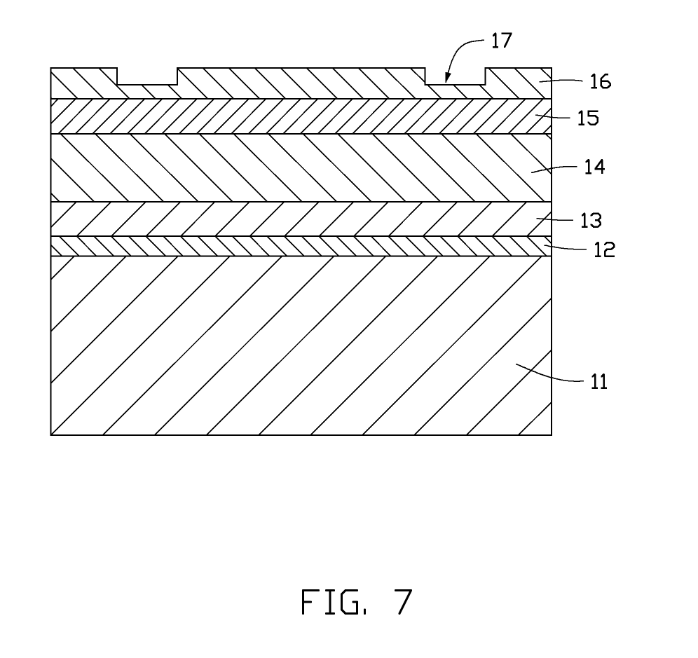

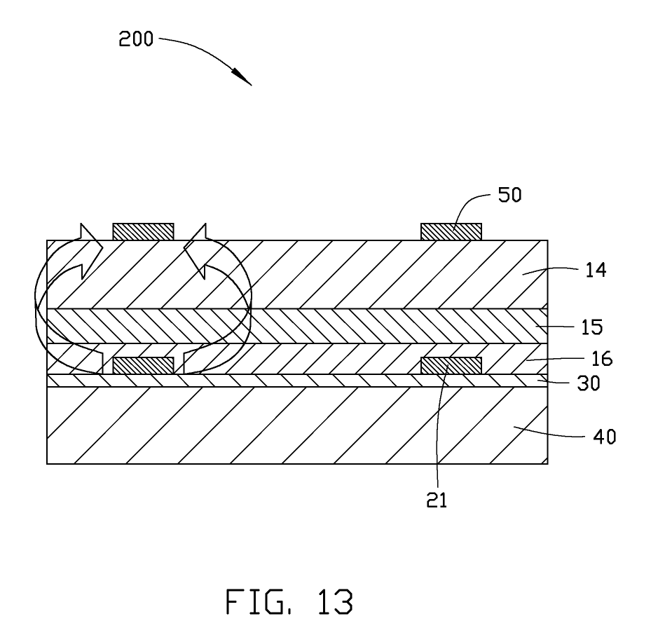

Referring to FIGS. 7 to 13, a method of manufacturing an LED die 200 in accordance with second embodiment of the disclosure is provided.

Referring to FIG. 7, a preformed LED structure 10 is provided. The LED structure 10 includes a first substrate 11, a nucleation layer 12, a buffer layer 13, an N-type layer 14, a muti-quantum well layer 15 and a P-type layer 16 successively formed along a height direction of the LED structure 10.

The first substrate 11 is flat and may be made of some materials such as sapphire, silicon carbide (SiC), silicon (Si) or gallium nitride (GaN) and so on. In this embodiment, the first substrate 11 is made of sapphire.

The top surface of the P-type layer 16 is etched to form a plurality of grooves 17 spaced from each other. Each groove 17 has a depth which is smaller than a height of the P-type layer 16. In this embodiment, the number of the grooves 17 is two and the two grooves 17 are spaced from each other.

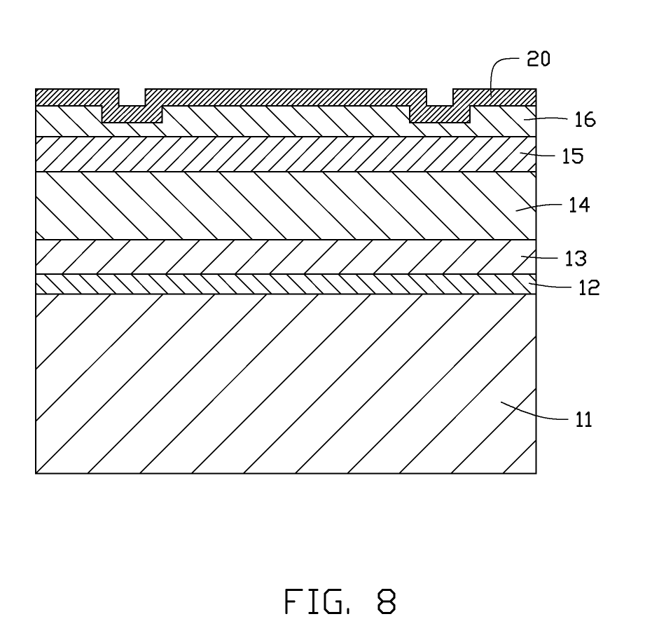

Referring to FIG. 8, an insulation layer 20 is formed on the P-type layer 16 with a part of the insulation layer being received in the grooves 17. The insulation layer 20 may be made of materials such as SiO₂, AlN or SiₓN_{y}. In this embodiment, the insulation layer 20 is made of SiO₂.

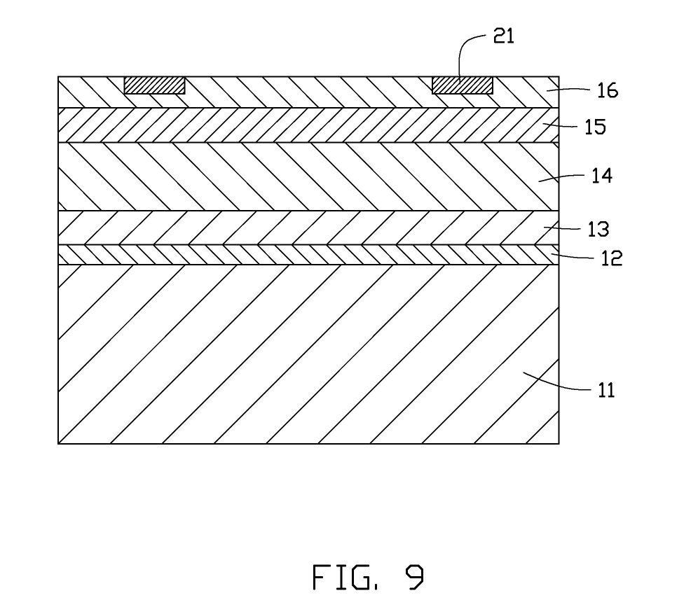

Referring to FIG. 9, a part of the insulation layer 20 on the P-type layer 16 without being received in the grooves 17 is removed, and a part of the insulation layer 20 received in the grooves 17 is retained to form a plurality of insulation blocks 21. A top surface of each of the insulation blocks 21 is coplanar with a top surface of the P-type layer 16. In this embodiment, the part of the insulation layer 20 on the P-type layer 16 without being etched to define the grooves 17 is removed by chemical-mechanical polishing method.

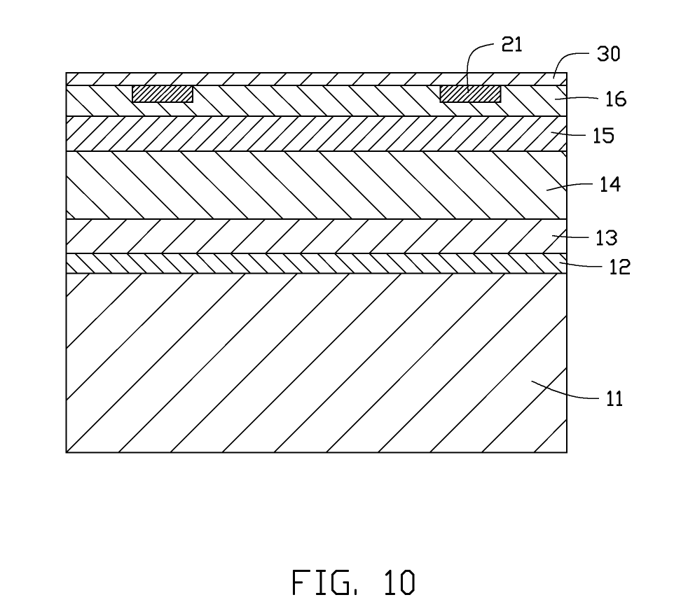

Referring to FIG. 10, a mirror layer 30 is formed on the P-type layer 16 and covers the insulation blocks 21. The mirror layer 30 is flat for strengthening outputs of light of the LED die 200.

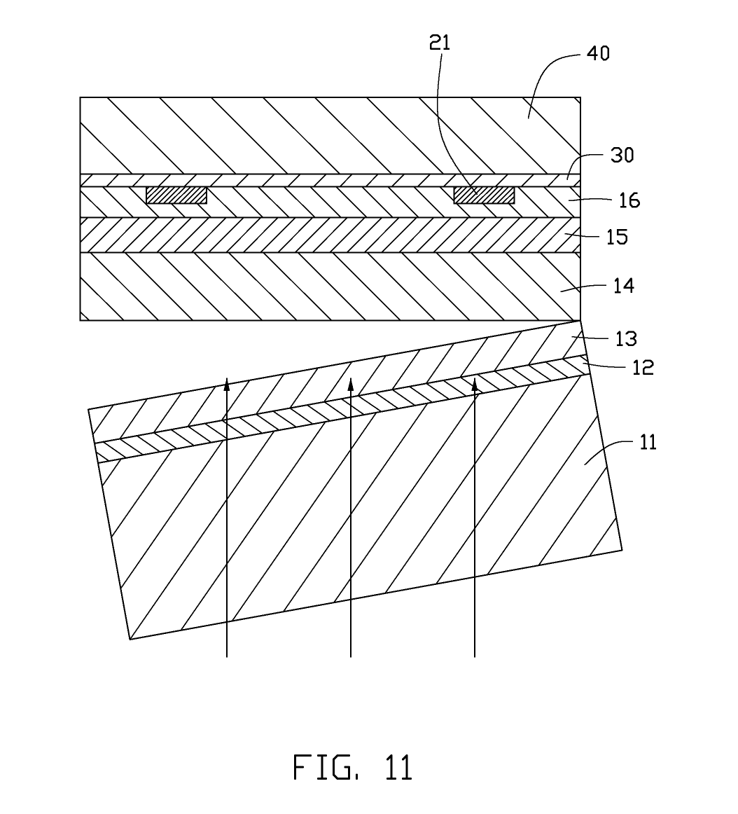

Referring to FIG. 11, a second substrate 40 is formed on the mirror layer 30 by electroplating or die bonding. The second substrate 40 is a conductive substrate. The second substrate 40 is a metal substrate made of metal materials such as Ti, Al, Ag, Ni, W, Cu, Pd, Cr or Au.

The first substrate 11, the nucleation layer 12 and the buffer layer 13 are removed from the LED structure 10 by laser separation method or chemical separation method, and a bottom surface of the N-type layer 14 originally adjacent to the buffer layer 13 is exposed in the air.

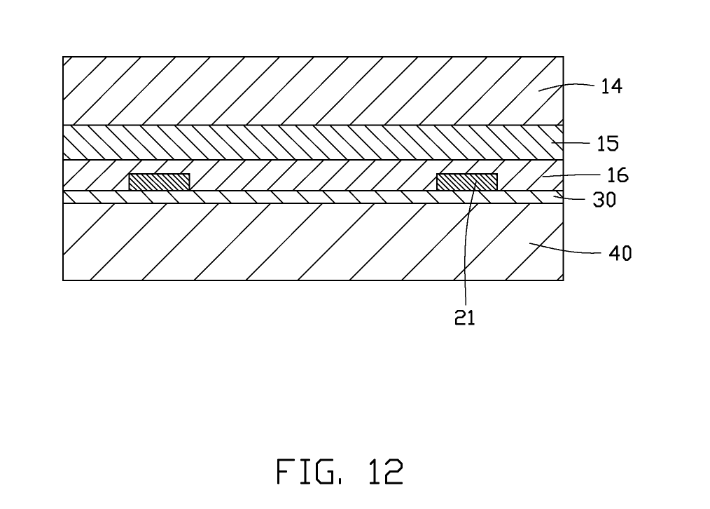

Referring to FIG. 12, the LED structure 10 is inverted, two N-electrodes 50 are disposed on the exposed surface of the N-type layer 14 corresponding to the locations of the insulation blocks 21. The N-electrodes 50 may be made of materials such as Ti, Al, Ag, Ni, W, Cu, Pd, Cr or Au. Each N-electrode 50 has a size the same as that of each insulation block 21.

When the LED die 200 works, the second substrate 40 and the N-electrodes 50 are respectively located at two opposite sides of the muti-quantum well layer 15. When a forward voltage is applied to the second substrate 40 and the N-electrodes 50, electrons inside the N-type layer 14 jump to electric holes inside the P-type layer 16 by excitation of an electric field; photons are emitted from the muti-quantum well layer 15 where the combinations of the electrons and the electric holes occur. Since the N-electrodes 50 correspond to the insulation block 21 in size and position, the current which may flow through the shortest path between the second substrate 40 and the N-electrodes 50 are blocked by the insulation blocks 21. The current evenly flows from the second substrate 40 to the N-type electrodes 50 via two opposite sides of each of the insulation blocks 21 by dodging the insulation blocks 21. Meanwhile, the life time of the LED die 200 is prolonged since heats generated by the LED die 100 are more evenly distributed in the LED die 200.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A method of manufacturing a light emitting diode (LED) die, comprising steps:
providing a preformed LED structure comprising a first substrate, and a nucleation layer, a buffer layer, an N-type layer, a muti-quantum well layer and a P-type successively formed on the first substrate;
forming an insulation block on the P-type layer;
forming a mirror layer on the P-type layer wherein the mirror layer covers the insulation block and the P-type layer;
forming a second substrate on the mirror layer, the second substrate being a electrically conductive substrate;
removing the first substrate, the nucleation layer and the buffer layer to expose a bottom surface of the N-type layer; and
disposing an N-electrode on the exposed surface of the N-type layer, the N-electrode being located corresponding to the insulation block.

2. The method of manufacturing the LED die of claim 1, wherein in the step of forming the insulation block, an insulation layer is formed on the P-type layer firstly, the insulation block being formed by etching the insulation layer.

3. The method of manufacturing the LED die of claim 1, wherein in the step of forming the insulation block, the P-type layer is etched to form a groove, an insulation layer is formed on the P-type layer with a first part of the insulation layer being received in the groove, and a second part of the insulation layer on the P-type layer without being received in the groove, and wherein the first part of the insulation layer is removed and the second part of the insulation layer received in the groove forms the insulation block.

4. The method of manufacturing the LED die of claim 3, wherein a top surface of the insulation block received in the groove is coplanar with a top surface of the P-type layer.

5. The method of manufacturing the LED die of claim 4, wherein the first part of the insulation layer on the P-type layer is removed by chemical-mechanical polishing method.

6. The method of manufacturing the LED die of claim 1, wherein the mirror layer is flat, and the second substrate is formed on the mirror layer by electroplating method or die bonding method.

7. The method of manufacturing the LED die of claim 1, wherein the insulation layer is made of silicon carbide, silicon or gallium nitride.

8. A method of manufacturing a light emitting diode (LED), comprising steps:
providing a preformed LED structure comprising a first substrate, and a nucleation layer, a buffer layer, an N-type layer, a muti-quantum well layer and an P-type successively formed on the first substrate;
forming a plurality of insulation blocks spaced from each other on the P-type layer;
forming a mirror layer on the P-type layer, the mirror layer covering the insulation blocks and the P-type layer;
forming a second substrate on the mirror layer, the second substrate being a electrically conductive substrate;
removing the first substrate, the nucleation layer and the buffer layer to expose a bottom surface of the nucleation layer; and
disposing a plurality of N-electrodes on the exposed surface of the N-type layer, the N-electrodes being located corresponding to the insulation blocks, respectively, the number of the N-electrodes being equal to that of the insulation blocks.

9. The method of manufacturing the LED die of claim 8, wherein in the step of forming the insulation blocks, an insulation layer is formed on the P-type layer firstly, the insulation blocks being formed by etching the insulation layer.

10. The method of manufacturing the LED die of claim 8, wherein in the step of forming the insulation blocks, the P-type layer is etched to form a plurality of grooves, an insulation layer is formed on the P-type layer with a first part of the insulation layer received in the grooves, and a second part of the insulation layer on the P-type layer without being received in the grooves, and wherein the second part of the insulation layer is removed and the first part of the insulation layer received in the grooves forms the insulation blocks.

11. The method for manufacturing the LED die of claim 8, wherein each insulation block has a size corresponding to that of each N-electrode.
